(19) United States
(12) Patent Application Publication
(10) Pub. No.: US 2026/0072078 A1
(43) Pub. Date: Mar. 12, 2026

(54) TEST APPARATUS AND METHOD FOR SETTING PARAMETERS

(71) Applicant: Tokyo Electron Limited, Tokyo (JP)

(72) Inventors: Shigeru KASAI, Yamanashi (JP); Yuki HIROSE, Yamanashi (JP)

(21) Appl. No.: 19/386,911

(22) Filed: Nov. 12, 2025

Related U.S. Application Data
(63) Continuation of application No. PCT/JP2024/017623, filed on May 13, 2024.

(30) Foreign Application Priority Data
May 26, 2023 (JP) 2023-087031

(51) Int. Cl. G01R 31/28; G01R 1/04

(52) U.S. Cl. CPC G01R 31/2891; G01R 1/04

(57) ABSTRACT

A test apparatus includes a base on which a substrate is to be mounted, an elevating mechanism configured to raise and lower the base, a test unit configured to test the substrate while contacting the substrate that is raised and lowered, and a controller. The controller is configured to control the elevating mechanism, generate a disturbance in the elevating mechanism at a position where the test unit contacts the substrate, acquire a dynamic characteristic of the elevating mechanism due to the disturbance, and set one or more parameters during upward movement of the elevating mechanism, based on the dynamic characteristic of the elevating mechanism.

### CROSS-REFERENCE TO RELATED APPLICATIONS

This application is a continuation of International Application No. PCT/JP2024/017623, filed on May 13, 2024 and designating the U.S., which claims priority to Japanese Patent Application No. 2023-087031, filed on May 26, 2023, the contents of which are incorporated herein by reference in their entirety.

### TECHNICAL FIELD

The present disclosure relates to a test apparatus and a method for setting parameters.

### BACKGROUND

Patent Document 1 discloses a stage (test stage) that transfers a wafer to a predetermined position in a test apparatus for testing the wafer. The stage supports a base (mounting base) on which the wafer is mounted, by using three elevation drive mechanisms. The stage also raises and lowers the base while monitoring elevation positions of the three elevation drive mechanisms.

The test apparatus raises the wafer to bring numerous probes (for example, tens of thousands) into contact with the wafer during the wafer test. In this case, a large load (torque) is applied to the base via the wafer from the probes. The load that acts on the base during rising varies due to causes such as a probe card tilt, variation between the probes, and probe wear from use.

### RELATED-ART DOCUMENT

Patent Document 1: Japanese Unexamined Patent Application Publication No. 2000-260852

### SUMMARY

A test apparatus includes a base on which a substrate is to be mounted, an elevating mechanism configured to raise and lower the base, a test unit configured to test the substrate while contacting the substrate that is raised and lowered, and a controller. The controller is configured to control the elevating mechanism, generate a disturbance in the elevating mechanism at a position where the test unit contacts the substrate, acquire a dynamic characteristic of the elevating mechanism due to the disturbance, and set one or more parameters during upward movement of the elevating mechanism, based on the dynamic characteristic of the elevating mechanism.

### BRIEF DESCRIPTION OF THE DRAWINGS

FIG. 1 is a cross-sectional view schematically illustrating a test apparatus according to an embodiment.

FIG. 2A is a schematic side view illustrating a stage provided in a test unit.

FIG. 2B is a plan view illustrating a mounting surface of the stage.

FIG. 3 is a side sectional view schematically illustrating a Z-axis movement mechanism for the stage.

FIG. 4A is a flowchart illustrating a method for operating the stage when raising the wafer.

FIG. 4B is a graph illustrating torque applied to a base when raising the wafer.

FIG. 5 is a block diagram illustrating a control flow of a Z-axis movement mechanism in a position control step.

FIG. 6 is a block diagram illustrating a control flow of the Z-axis movement mechanism in a torque control step.

FIG. 7 is a block diagram illustrating a control algorithm of each motor mechanism.

FIG. 8 is an equivalent circuit diagram illustrating the concept of system identification for probes and the Z-axis movement mechanism.

FIG. 9 is a functional block diagram illustrating a stage controller in the system identification.

FIG. 10 is a flowchart illustrating a method for setting parameters.

### DETAILED DESCRIPTION

Various embodiments of the present disclosure will be described below with reference to the drawings. In each of the drawings, the same components are denoted by the same reference numerals, and duplicate description may be omitted.

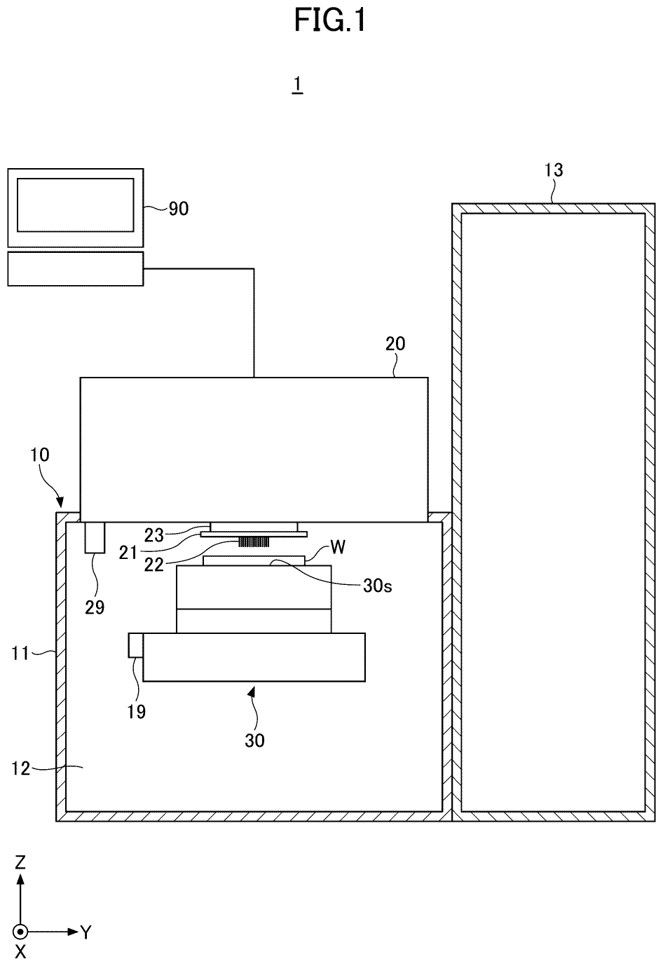

FIG. 1 is a cross-sectional view schematically illustrating a test apparatus 1 according to an embodiment. As illustrated in FIG. 1, the test apparatus 1 tests electrical characteristics of a wafer W, which is an example of a substrate. For example, semiconductor devices, each of which is a device under test (DUT), are formed on the surface of the wafer W. The substrate is not limited to the wafer W, and may include a carrier, a glass substrate, a single chip, an electronic circuit board, or the like on which the DUT is placed. The DUT is not limited to the semiconductor device, and may be other electronic devices.

The test apparatus 1 includes a test unit 10 that performs the test, a loader 13 disposed at a position adjacent to the test unit 10, and a tester 20 disposed on the test unit 10. Further, the test apparatus 1 includes a controller 90 that controls the operation of the test unit 10, the loader 13, and the tester 20.

The test unit 10 includes a rectangular parallelepiped housing 11, and has a test chamber 12 in the housing 11. The test chamber 12 houses the stage 30 on which the wafer W is mounted, and that transfers the wafer W to a desired three-dimensional coordinate position.

A front opening unified pod (FOUP), not illustrated, for holding wafers W is set in the loader 13. The loader 13 includes a transfer device (not illustrated). A given wafer W is taken out from the FOUP by the transfer device, and is transferred to the stage 30 in the test chamber 12. The loader 13 takes out a tested wafer W from the stage 30 by the transfer device, and accommodates the wafer W in the FOUP.

The test unit 10 includes a probe card 21 that is connected to the tester 20 via an interface 23 and is in an upper space of the test chamber 12. The probe card 21 has probes 22 at positions that face the wafer W. When moving the wafer W by the stage 30, each probe 22 contacts an electrode pad, a solder bump, or the like of each DUT for the wafer W. In this arrangement, the tester 20 outputs power and various signals to DUTs via the probe card 21 and the interface 23, and then receives signals transmitted from the DUTs via the probe card 21 and the interface 23.

The tester 20 has an internal motherboard (not illustrated) connected to the interface 23. The motherboard has slots into which test boards (not illustrated) are inserted, and is connected to the controller 90. The motherboard determines whether each DUT passes or fails based on the signal transmitted from the DUT for the wafer W. The tester 20 can perform different types of tests by appropriately replacing the test board.

Further, the test apparatus 1 may include a test-side camera 29 that captures the wafer W on the stage 30 at an appropriate position in the test chamber 12. The test-side camera 29 captures, for example, the inclination of the stage 30 and/or a position or the like of the wafer W that is mounted on the stage 30. Also, the test apparatus 1 may include either the probe card 21 or a stage-side camera 19 that captures a contact state or the like between each probe 22 and the wafer W.

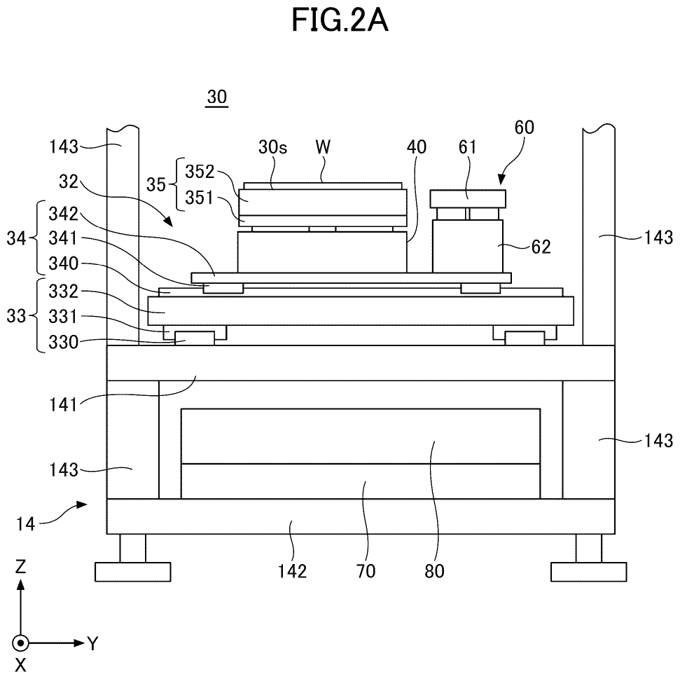

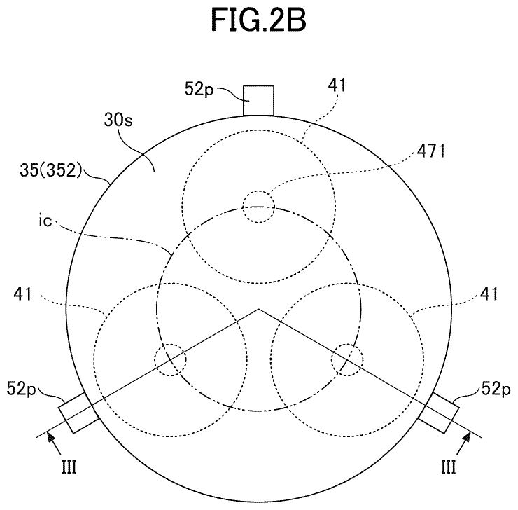

FIG. 2A is a schematic side view illustrating the stage 30 provided in the test unit 10. FIG. 2B is a plan view illustrating a mounting surface 30s of the stage 30. As illustrated in FIG. 2A, the stage 30 is provided on a frame structure 14 of the housing 11. The mounting surface 30s that is flat and supports the wafer W is formed on the upper surface of the stage 30.

The stage 30 transfers the wafer W mounted on 30s the mounting surface to an appropriate three-dimensional position (in an X-axis direction, a Y-axis direction, and a Z-axis direction) of the test chamber 12. For example, the stage 30 moves in a horizontal direction (X-axis and Y-axis directions) between a position near (or inside) the loader 13 and a position facing the probe card 21, to thereby adjust a horizontal position of the wafer W. The stage 30 also moves vertically (in the Z-axis direction) at a facing position between the probe card 21 and the wafer W, to thereby adjust an elevation position of the wafer W.

The stage 30 has a moving unit 32 (an X-axis movement mechanism 33, a Y-axis movement mechanism 34, and a Z-axis movement mechanism 40), a base 35, a probe polishing mechanism 60, a stage controller 70, and a motor drive unit 80. In this arrangement of the stage 30, the frame structure 14 has a two-stage structure that includes an upper base 141 supporting the moving unit 32; a lower base 142 supporting the stage controller 70 and/or the motor drive unit 80; and supports 143 that support respective bases.

The X-axis movement mechanism 33 of the moving unit 32 includes guide rails 330 that are fixed to the upper surface of the upper base 141 and extend along the X-axis direction; X-axis movable bodies 331 that are arranged on the respective guide rails 330; and an X-axis stage 332 supported by the X-axis movable bodies 331. The X-axis stage 332 has an X-axis drive unit (a motor, a gear mechanism, and the like), not illustrated, connected to the motor drive unit 80. The X-axis drive unit reciprocates the X-axis movable bodies 331 and the X-axis stage 332 in the X-axis direction, based on power supply from the motor drive unit 80, to thereby adjust an X-coordinate of the wafer W.

The Y-axis movement mechanism 34 includes guide rails 340 that are fixed to the upper surface of the X-axis stage 332 and extend along the Y-axis direction; Y-axis movable bodies 341 that are arranged on the respective guide rails 340; and a Y-axis stage 342 supported by the Y-axis movable bodies 341. The Y-axis stage 342 has a Y-axis drive unit (a motor, a gear mechanism, and the like), not illustrated, connected to the motor drive unit 80. The Y-axis drive unit causes the Y-axis movable bodies 341 and the Y-axis stage 342 to reciprocate in the axial direction, based on power supply from the motor drive unit 80, to thereby adjust a Y-coordinate of the wafer W.

The Z-axis movement mechanism 40 is provided on the Y-axis stage 342, and holds the base 35 above the Y-axis stage 342. By displacing the base 35 in the Z-axis direction (vertical direction), the Z-axis movement mechanism 40 constitutes an elevation mechanism of the embodiment for raising and lowering the wafer W that is mounted on the mounting surface 30s of the base 35. A configuration of the Z-axis movement mechanism 40 will be described in detail later.

The base 35 that is transferred by the moving unit 32 includes a bottom plate 351 supported by the Z-axis movement mechanism 40, and includes a chuck top 352 that is laminated on the upper side of the bottom plate 351 and that has the mounting surface 30s. The bottom plate 351 is supported by three drive units 41 of the Z-axis movement mechanism 40 described later. The chuck top 352 has a circular shape that is larger in diameter than the wafer W in plan view (see FIG. 2B), and the chuck top 352 is formed to have a thickness that is greater than that of the bottom plate 351. Although not illustrated, the chuck top 352 may include an appropriate holding unit (such as a vacuum adsorption mechanism or a mechanical chuck) that holds the wafer W; a temperature control mechanism that adjusts the temperature of the mounting surface 30s; a temperature sensor that detects the temperature of the mounting surface 30s; and other components.

The probe polishing mechanism 60 of the stage 30 is provided at a position of the Y-axis stage 342 adjacent to the Z-axis movement mechanism 40. A polishing body 61 for polishing the probes 22 that protrude downward from the probe card 21 is provided at an upper portion of the probe polishing mechanism 60. The probe polishing mechanism 60 has a polishing-side Z-axis movement mechanism 62 that displaces the polishing body 61 in the Z-axis direction. The polishing-side Z-axis movement mechanism 62 is configured substantially similarly to the Z-axis movement mechanism 40.

The stage controller 70 is connected to the controller 90 (see FIG. 1) of the test apparatus 1, and controls the operation of the stage 30 based on a command from the controller 90. The stage controller 70 has, for example, a main controller that controls the operation of the entire stage 30; a programmable logic controller (PLC) that controls the operation of the moving unit 32; a temperature controller that controls the temperature control mechanism; an illumination controller; a power supply unit; and other components (all not illustrated). The main controller of the stage controller 70 may be implemented by a computer built-in board having one or more processors, a memory, an input/output interface, an electronic circuit, and other components, which are not illustrated. The one or more processors are a combination of one or more selected from CPUs, GPUs, ASICs, FPGAS, circuits comprised of discrete semiconductors, and other components. The one or more processors execute and process one or more programs that are stored in a memory. The memory may include a non-volatile memory and a volatile memory.

The stage controller 70 controls the motor drive unit 80 based on a command from the controller 90, and after the wafer W is moved from the loader 13 to the base 35, the stage controller 70 operates the moving unit 32 to thereby move the wafer W in the horizontal direction. Then, at a position where the wafer W faces the probe card 21, the stage controller 70 raises the base 35 by the Z-axis movement mechanism 40 of the moving unit 32, so that the wafer W is in contact with one or more probes 22 of the probe card 21. In this state, the controller 90 starts an electrical test through the tester 20. After the test through the tester 20 is completed, the stage controller 70 lowers and horizontally moves the tested wafer W by performing a reverse operation of the movement operation described above. As a result, the stage controller 70 returns the wafer W to the loader 13.

As illustrated in FIG. 2B, the Z-axis movement mechanism 40 has the three drive units 41 that independently raise and lower the base 35, and each drive unit 41 supports the base 35. Shafts of the drive units 41 are located on a virtual circle ic that is separated by a predetermined radius from the center of the base 35, and these shafts are arranged at equal intervals along a circumferential direction of the virtual circle ic (every 120° around the center of the base 35). By individually raising and lowering each of the drive units 41 as arranged above, the Z-axis movement mechanism 40 can adjust the tilt of the base 35.

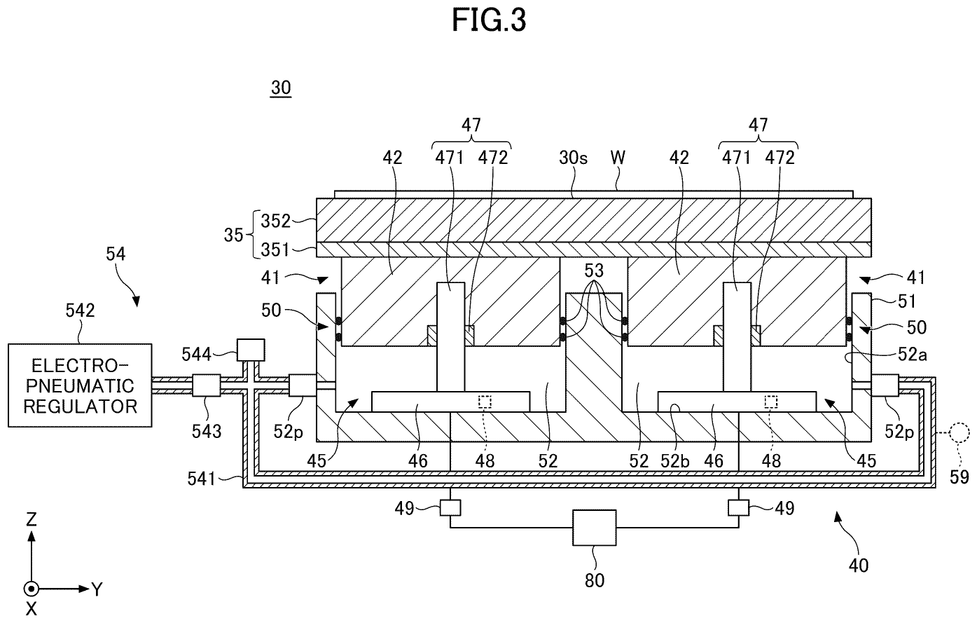

FIG. 3 is a side sectional view schematically illustrating the Z-axis movement mechanism 40 of the stage 30. As illustrated in FIG. 3, each of the three drive units 41 has a Z-axis movable body 42 that directly supports the bottom plate 351 of the base 35 and that can displace in the vertical direction. Each of the drive units 41 according to the embodiment has two mechanisms that raise and lower the Z-axis movable body 42, namely, a motor mechanism 45 and a cylinder mechanism 50.

The motor mechanism 45 has a drive motor 46 that drives rotation based on the power supply from a motor drive unit 80. The type of the drive motor 46 is not particularly limited, but it is preferable to use a direct drive motor in order to make the Z-axis movement mechanism 40 compact. The direct drive motor is configured to be short along the axial direction of the drive unit 41, without using a reduction gear, and the direct drive motor can rotate at low velocity and high torque.

The motor mechanism 45 also has a power conversion unit 47 that converts the rotational drive of the drive motor 46 into linear drive, between the drive motor 46 and the Z-axis movable body 42. For example, the power conversion unit 47 may have a ball screw structure having both a ball screw 471 connected to a rotor (not illustrated) of the drive motor 46 and a nut 472 screwed to the outer peripheral surface of the ball screw 471. In this case, the ball screw 471 constitutes a shaft of each drive unit 41. With use of such a power conversion unit 47, the motor mechanism 45 rotates the ball screw 471 according to the rotation of the drive motor 46, and thus raises and lowers the Z-axis movable body 42 along the Z-axis direction.

Further, the motor mechanism 45 may include an encoder 48 that detects a rotation angle of the motor; a current sensor 49 that detects, as a current value, a load applied to the drive motor 46 from the base 35; and other components. Here, if a speed reducer is connected to the drive motor 46, the torque of the drive motor 46 needs to be determined with consideration of the torque of the speed reducer. However, in the present embodiment, since the direct drive motor is applied to the drive motor 46, loss in torque transmission of the speed reducer no longer needs to be taken into consideration. Thus, the stage 30 can accurately detect the torque that is applied to the drive motor 46, through the current sensor 49.

On the other hand, the cylinder mechanism 50 has a cylindrical recess 52 in a disk-shaped housing 51 of the Z-axis movement mechanism 40 that houses the motor mechanism 45, and the cylinder mechanism 50 causes the Z-axis movable body 42 itself, which is housed in the recess 52, to function as a piston. The cylinder mechanism 50 supplies and discharges air, which is a pressure medium, to the recess 52, thereby applying appropriate pressure (a floating force) to the lower surface of the Z-axis movable body 42. In this arrangement, the Z-axis movement mechanism 40 assists the raising and lowering of each Z-axis movable body 42, and thus the torque of each motor mechanism 45 can be reduced.

Specifically, in the disk-shaped housing 51, the recesses 52 are surrounded by: an inner peripheral surface 52a extending parallel to the vertical direction; and a bottom surface 52b parallel to the horizontal direction. These recesses 52 are opened at an upper portion of the disk-shaped housing 51. The above drive motor 46 is disposed on the bottom surface 52b. On the other hand, each Z-axis movable body 42 has one or more seal members 53 in contact with the inner peripheral surface 52a of the recess 52, on the outer peripheral surface (side peripheral surface) of the movable body. Each seal member 53 is made of an elastic material such as an elastomer, and one or more given seal members 53 allow a given Z-axis movable body 42 to slide in the vertical direction while hermetically closing the recess 52 between the outer peripheral surface and the inner peripheral surface 52a of the Z-axis movable body 42. Each seal member 53 may be provided on the inner peripheral surface 52a of the recess 52.

In the cylinder mechanisms 50, a supply/discharge mechanism 54 that provides or discharges air to the recesses 52 that are closed by the Z-axis movable bodies 42 is disposed outside the disk-shaped housing 51. The supply/discharge mechanism 54 connects a supply/discharge path 541 to ports 52p in communication with the recesses 52 of the disk-shaped housing 51. Further, the supply/discharge mechanism 54 has an electro-pneumatic regulator 542 connected to one end of the supply/discharge path 541, and has an open-close valve 543 and a relief valve 544 in the supply/discharge path 541 that is situated between a given recess 52 and the electro-pneumatic regulator 542.

The supply/discharge path 541 is configured by connecting pipes with internal air flow paths. The supply/discharge path 541 branches at an intermediate position of the supply/discharge path, depending upon the number of recesses 52 of the drive units 41. One end of each branch path of the supply/discharge path 541 is connected to a corresponding port 52p of the disk-shaped housing 51.

A primary side of the electro-pneumatic regulator 542 is connected to an air source such as a compressor (not illustrated), and the supply/discharge path 541 is connected to a secondary side of the electro-pneumatic regulator 542. The electro-pneumatic regulator 542 is connected to the stage controller 70, and supplies air adjusted to appropriate pneumatic pressure, to the supply/discharge path 541, under the control of the stage controller 70.

The open-close valve 543 is disposed on an upstream side of the supply/discharge path 541 in an air supply direction from the branch position. The open-close valve 543 is connected to the stage controller 70, and opens and closes a flow path of the supply/discharge path 541 under the control of the stage controller 70.

The relief valve 544 is disposed on a downstream side (for example, the branch position of the supply/discharge path 541) of the open-close valve 543. The relief valve 544 is connected to the stage controller 70, and switches between atmospheric release and isolation of a flow path of the supply/discharge path 541, under the control of the stage controller 70.

The stage controller 70 (see FIG. 2A) moves the stage 30 to a position facing the probe card 21. Then, by cooperating of the motor mechanisms 45 and the cylinder mechanisms 50 of the drive units 41, the stage controller 70 raises and lowers the wafer W on the base 35 through the drive units 41. For example, when raising the wafer W, the stage controller 70 controls the position of the base 35 in the Z-axis direction by the motor mechanism 45, while canceling or compensating for the self-weight of the base 35 based on the pneumatic pressure from the cylinder mechanism 50. The control of the Z-axis movement mechanism 40 by the stage controller 70 will be described in detail below.

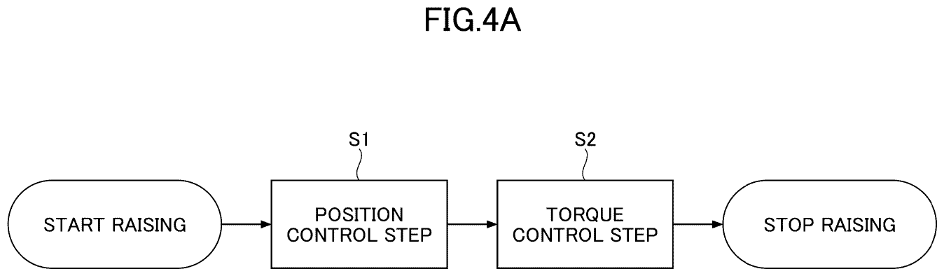

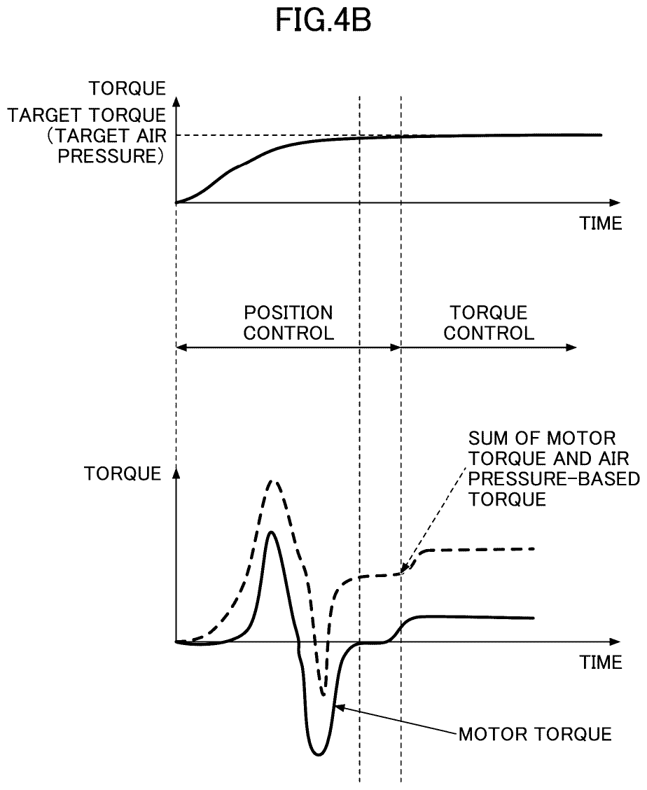

FIG. 4A is a flow diagram illustrating the method for operating the stage 30 when raising the wafer W. FIG. 4B is a graph illustrating the torque applied to the base 35 when raising the wafer W. As illustrated in FIG. 4A, the stage controller 70 sequentially performs a position control step (S1) and a torque control step (S2), when raising the wafer W mounted on the base 35. The position control step (S1) is a control performed during a period until each probe 22 of the probe card 21 contacts the wafer W. After each probe 22 contacts the wafer W, the torque control step (S2) is a control performed both during overdrive when the base 35 is slightly raised, and during testing of the wafer W.

That is, in the position control step (S1), the stage controller 70 adjusts an elevation position (or a 3D position including X-axis and Y-axis directions) of the wafer W, and causes the DUTs for the wafer W to contact the respective probes 22. When performing the position control step (S1), the stage controller 70 drives the electro-pneumatic regulator 542 to supply air to each recess 52, and adjusts pneumatic pressure in each recess 52 to target pressure. The target pressure in each recess 52 is pressure that can compensate for the self-weight of the base 35, and is obtained by holding a weight value of the base 35 in advance and by calculating required pneumatic pressure based on the weight value. In this arrangement, the motor mechanism 45 greatly reduces (or makes zero) the torque for raising of the base 35 itself. The self-weight of the base 35 may include the weight of the Z-axis movable bodies 42 and/or the weight of the wafer W.

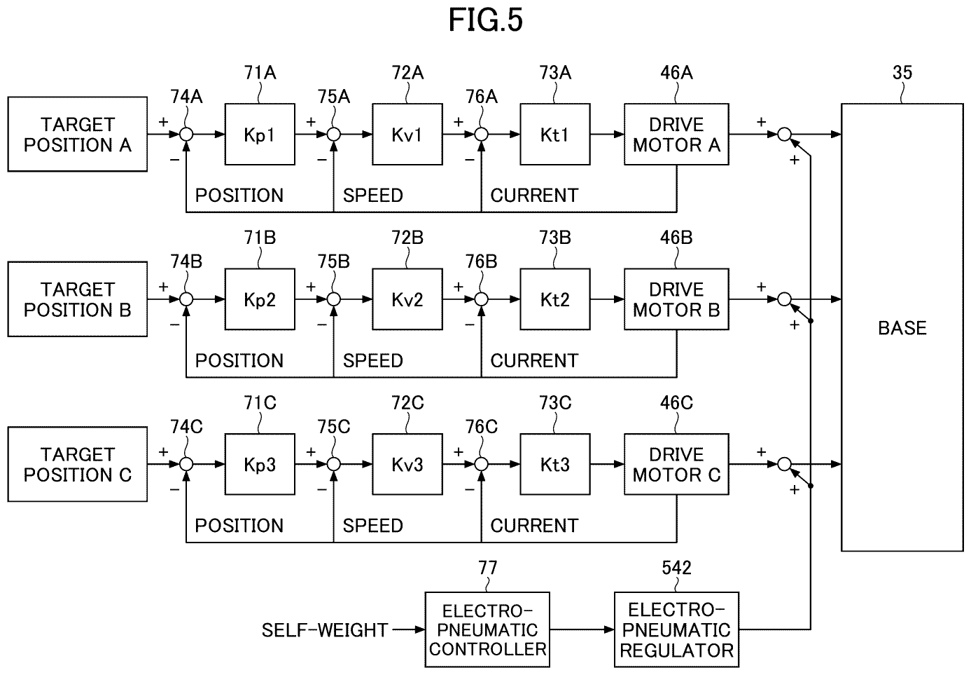

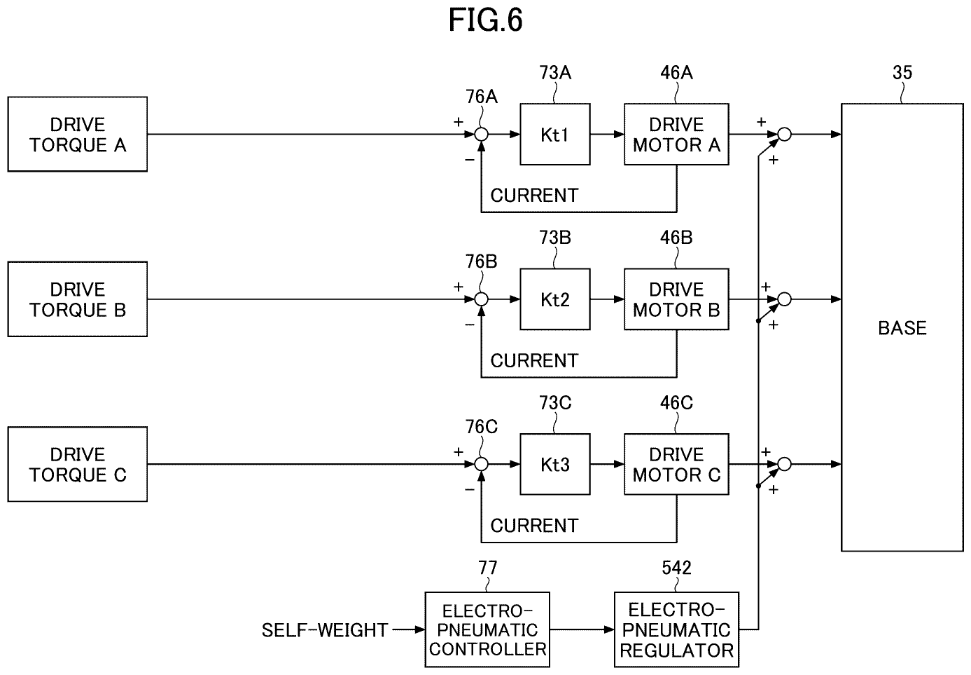

FIG. 5 is a block diagram illustrating the control flow of each Z-axis movement mechanism 40 in the position control step. In FIG. 5 and FIG. 6 described below, the three drive motors 46 are labeled with the symbols A, B, and C for ease of understanding. In the position control step (S1), the Z-axis movement mechanism 40 detects a position (rotation angle), velocity, and current (acceleration) of each drive motor 46 as illustrated in FIG. 5, and transmits, as state information, information of the position, velocity, and current to the stage controller 70 or the motor drive unit 80. The position, velocity, and acceleration of each drive motor 46 can be obtained from the encoder 48 that is provided in a corresponding drive unit 41. Alternatively, the current of each drive motor 46 may be directly detected by a corresponding current sensor 49. In the following, the state information that is detected in each drive motor 46 may be referred to as an actual position, an actual velocity, and an actual current (actual acceleration).

As functional units that drive the drive motors 46A, 46B, and 46C of the respective drive units 41, the stage controller 70 (or the motor drive unit 80) includes first calculation units 71A, 71B, and 71C, second calculation units 72A, 72B, and 72C, and third calculation units 73A, 73B, and 73C. The stage controller 70 further has first differential units 74A, 74B, and 74C on an input side of the respective first calculation units 71A, 71B, and 71C; second differential units 75A, 75B, and 75C upstream of the respective second calculation units 72A, 72B, and 72C; and third differential units 76A, 76B, and 76C on an input side of the respective third calculation units 73A, 73B, and 73C. The first calculation units 71A to 71C, the second calculation units 72A to 72C, the third calculation units 73A to 73C, the first differential units 74A to 74C, the second differential units 75A to 75C, and the third differential units 76A to 76C are software functional units according to the embodiment. However, these units are not limited to the software functional units, and may be hardware functional that use discrete semiconductors.

Target positions A, B, and C of the drive motors 46A, 46B, and 46C, and actual positions of the drive motors 46A, 46B, and 46C are input to the first differential units 74A, 74B, and 74C, respectively. In this arrangement, the first differential units 74A, 74B, and 74C calculate differences between the target positions A, B, and C and the actual positions, respectively. Similarly, target velocities and actual velocities of the drive motors 46A, 46B, and 46C are input to the second differential units 75A, 75B, and 75C, respectively. In this arrangement, the second differential units 75A, 75B, and 75C calculate the differences between the target velocities and the actual velocities, respectively. Target currents and actual currents of the drive motors 46A, 46B, and 46C are input to the third differential units 76A, 76B, and 76C, respectively. In this arrangement, the third differential units 76A, 76B, and 76C calculate the differences between the target currents and the actual currents, respectively. The actual currents of the drive motors 46A, 46B, and 46C are proportional to the torque (=acceleration) applied to the drive motors 46A, 46B, and 46C, respectively. In this arrangement, the third differential units 76A, 76B, and 76C may be each configured to calculate the difference between the target acceleration and the actual acceleration, by converting the target into current the target acceleration.

The first calculation units 71A, 71B, and 71C respectively calculate correction positions that are used to adjust the positions based on position differences that are input from the first differential units 74A, 74B, and 74C. Further, the first calculation units 71A, 71B, and 71C respectively calculate the target velocities corresponding to the correction positions. The second calculation units 72A, 72B, and 72C respectively calculate correction velocities that are used to adjust velocities of the drive motors 46A, 46B, and 46C based on velocity differences that are input from the second differential units 75A, 75B, and 75C. Further, the second calculation units 72A, 72B, and 72C respectively calculate target currents corresponding to the correction velocities. The third calculation units 73A, 73B, and 73C respectively calculate amounts of power supplied to the drive motors 46 based on current differences that are input from the third differential units 76A, 76B, and 76C. The rotation drive of the drive motor 46A, 46B, and 46C is controlled according to the respective amounts of power supplied from the stage controller 70.

In order to control the electro-pneumatic regulator 542 for the cylinder mechanisms 50, the stage controller 70 has an interior electro-pneumatic controller 77. The electro-pneumatic controller 77 retrieves the self-weight (a weight value) of the base 35 from the memory, then calculates target torque (i.e., target pneumatic pressure) applied to the base 35 according to the self-weight of the base 35, and controls the electro-pneumatic regulator 542 according to the target pneumatic pressure. Based on a command from the electro-pneumatic controller 77, the electro-pneumatic regulator 542 uniformly supplies the pneumatic pressure to the recesses 52 for the three drive units 41, to thereby apply pneumatic pressure enabling the self-weight of the base 35 to be canceled, to each Z-axis movable body 42.

In this arrangement, in the position control step (S1), by current control that does not use the self-weight of the base 35, the drive motors 46A, 46B, and 46C of the drive units 41 can adjust a relative elevation position of the wafer W and the base 35, with respect to each probe 22.

FIG. 6 is a block diagram illustrating the control flow of each Z-axis movement mechanism 40 in the torque control step. As illustrated in FIG. 6, in the torque control step (S2), the Z-axis movement mechanism 40 detects the current (torque) of each drive motor 46, and transmits a detection signal of the actual current as state information, to the stage controller 70 or the motor drive unit 80.

The stage controller 70 (or the motor drive unit 80) includes the third calculation units 73A, 73B, and 73C and the third differential units 76A, 76B, and 76C, as functional units that drive the drive motors 46A, 46B, and 46C of the drive units 41. In other words, in the torque control step (S2), the first calculation units 71A, 71B, and 71C, the second calculation units 72A, 72B, and 72C, the first differential units 74A, 74B, and 74C, and the second differential units 75A, 75B, and 75C are omitted.

Target drive torques A, B, and C of the drive motors 46A, 46B, and 46C are respectively input to the third differential units 76A, 76B, and 76C from the stage controller 70. For example, the target drive torques A, B, and C are calculated based on loads received from the probes 22, in an overdrive operation in which each DUT for the wafer W is raised so as to ensure the contact with the probe 22. The third differential units 76A, 76B, and 76C calculate differences between the target currents (target torques) that are obtained based on the target drive torques A, B, and C, and the actual currents (actual torques) of the drive motors 46A, 46B, and 46C.

The third calculation units 73A, 73B, and 73C receive the current differences that are calculated in the third differential units 76A, 76B, and 76C. The third calculation units 73A, 73B, and 73C respectively calculate amounts of power supplied to the drive motors 46A, 46B, and 46C based on the received current differences (such that the current differences become zero). The rotational drive of the drive motors 46A to 46C is controlled according to the respective amounts of power supplied from the stage controller 70.

In the torque control step (S2), the stage controller 70 also includes an interior electro-pneumatic controller 77, as described in the position control step (S1). The electro-pneumatic controller 77 calculates pneumatic pressure that is applied to the base 35, according to the self-weight of the base 35 that is stored in the memory. Then, the electro-pneumatic controller 77 controls the electro-pneumatic regulator 542 according to the pneumatic pressure.

In this arrangement, in the torque control step (S2), by only the current control that does not use a position and velocity, the drive motors 46A, 46B, and 46C of the drive units 41 can adjust positions of the wafer W and the base 35, with respect to each probe 22 in contact with the wafer W. That is, pneumatic pressures in the cylinder mechanisms 50 cancel the self-weight of the base 35, such that the drive motors 46A, 46B, and 46C apply torque only in response to mainly the loads received from the probes 22 in contact with the wafer W. As a result, the stage 30 can perform the overdrive operation with reduced torque.

Referring back to FIGS. 4A and 4B, by switching from the position control step (S1) to the torque control step (S2) during the raising of the wafer W, the stage controller 70 appropriately controls the position of the stage 30 in the Z-axis direction. As illustrated in the lower part of FIG. 4B, a motor torque obtained based on the pneumatic pressure in the cylinder mechanism 50 is added to the motor torque of each motor mechanism 45, thereby increasing the overall torque that is applied to the base 35 (see the dashed line of FIG. 4B).

Here, as illustrated in the upper part of FIG. 4B, the motor torque due to the pneumatic pressure in each cylinder mechanism 50 gradually increases from the start of the position control step (S1). On the other hand, the motor torque of each motor mechanism 45 that is obtained based on the power supply quickly changes according to a power supply amount. For example, in the position control step (S1), the motor torque of each motor mechanism 45 rapidly increases after the start of the position control step, then decreases, and increases again. Then, in the torque control step (S2), when applying the load from each probe 22 to the wafer W and the base 35, a substantially constant torque of each motor mechanism 45 is applied so as to correspond to the load of each probe 22.

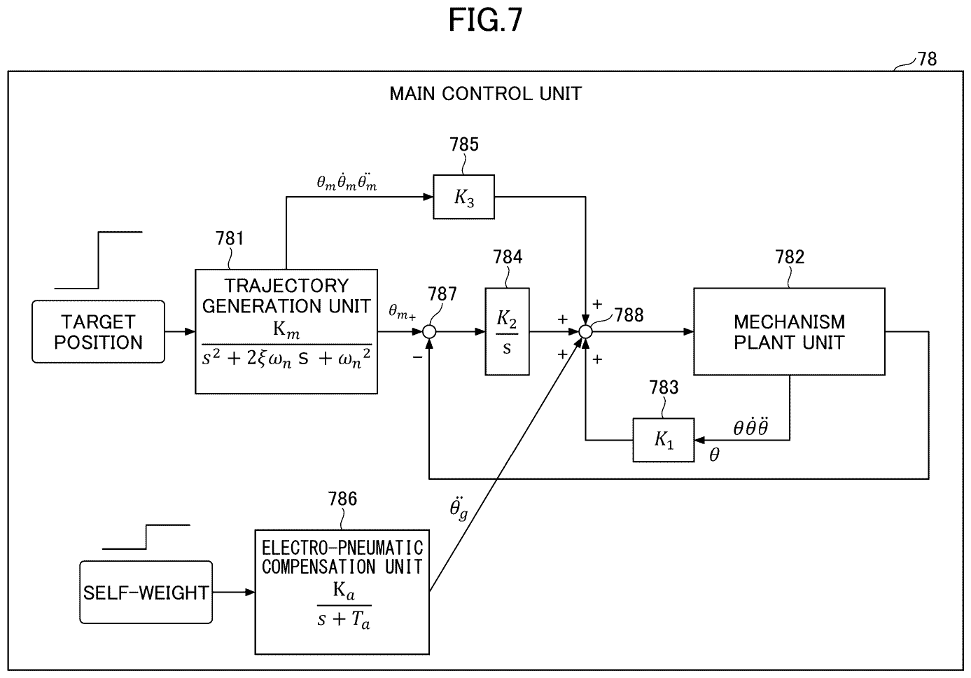

In other words, in the position control step (S1), a delay time occurs in the torque due to the pneumatic pressure of each cylinder mechanism 50, with respect to the target current (target torque) that enables the self-weight of the base 35 to be canceled. In this arrangement, in the position control step (S1), for an electric line of each motor mechanism 45, the stage controller 70 according to the present embodiment performs model following control as illustrated in FIG. 7. FIG. 7 is a block diagram illustrating a control algorithm of each motor mechanism 45.

In the model following control, each drive motor 46 is controlled so as to eliminate the delay time in the torque due to the pneumatic pressure in the cylinder mechanism 50. The stage controller 70 determines a drive state of each motor mechanism 45 by using both the target position of a corresponding drive unit 41 and the self-weight of the base 35, as inputs in the model following control. The “target position” of each drive unit 41 is a position profile indicating a trajectory of the wafer W obtained when raising the wafer W. The target position of each drive unit 41 is calculated based on (i) a position obtained upon completion of the translation movement of the stage 30, (ii) a scheduled contact position of each probe 22 of the probe card 21 with the wafer W, and (iii) a position or the like at which conduction between each probe 22 and the wafer W is completed. Further, the stage controller 70 may detect the inclination of the wafer W with respect to each probe 22, based on image information or the like from the stage-side camera 19 and the test-side camera 29, and then the stage controller 70 may calculate one or more target positions that are used to correct the inclination of the wafer W.

The stage controller 70 has an interior main controller 78 that performs the model following control. The interior of the main controller 78 has a trajectory generation unit 781, a mechanism plant unit 782, a first calculation unit 783, a second calculation unit 784, a third calculation unit 785, an electro-pneumatic compensation unit 786, a first adder 787, and a second adder 788.

In response to receiving the target position, the trajectory generation unit 781 is configured to calculate trajectories of the wafer W and the base 35 during the raising of the wafer and the base. In other words, the trajectory generation unit 781 calculates a position, velocity, and acceleration (current) of each drive motor 46 for each unit time. For example, the trajectory generation unit 781 preliminarily stores an appropriate function capable of generating the trajectory, and calculates the trajectory based on a given target position. As an example of this function, the following equation is used.

$${K}_{m} / ( {s}^{2} + 2 {ξω}_{n} s + {ω}_{n}^{2} )$$

Here, Kₘ is an amount of trajectory movement, ξ is a parameter of an overshoot amount, and on is a parameter of response speed.

The trajectory generation unit 781 calculates the trajectory (position, velocity, and acceleration) of each drive motor 46, then outputs trajectory values to the third calculation unit 785, and outputs the trajectory values to the first adder 787.

The mechanism plant unit 782 outputs the power supply amount calculated by the model following control to each motor mechanism 45, and feeds back the actual position, actual velocity, and actual acceleration of each drive motor 46 that are detected by a corresponding motor mechanism 45. For example, the mechanism plant unit 782 outputs the actual position, actual velocity, and actual acceleration of each motor mechanism 45 to the first calculation unit 783, and outputs the actual position of each drive motor 46 to the first adder 787.

The first calculation unit 783 integrates both (i) actual state variables (actual position, actual velocity, and actual acceleration) of each drive motor 46 that are received from the mechanism plant unit 782 and (ii) coefficient K1 defined in a design of the model following control, to thereby calculate state variables for correction of each drive motor 46.

The first adder 787 calculates a difference between the position of each drive motor 46 received from the trajectory generation unit 781, and the actual position of a corresponding drive motor 46 received from the mechanism plant unit 782, and outputs the difference to the second calculation unit 784.

The second calculation unit 784 is an integrator that integrates coefficient K2 defined in the design of the model following control and that integrates a difference calculated by the first adder 787. In this arrangement, the second calculation unit 784 can obtain a position steady-state error (error) of each motor mechanism 45. The position steady-state error is sent to the second adder 788, and is used as a state variable for correction.

The third calculation unit 785 integrates both (i) the trajectory (position, velocity, and acceleration) of each drive motor 46 received from the trajectory generation unit 781 and (ii) coefficient K3 defined in the design of the model following control, to thereby calculate state variables for trajectory tracking of each drive motor 46.

In response to receiving the self-weight of the base 35, the electro-pneumatic compensation unit 786 determines the pneumatic pressure from the electro-pneumatic regulator 542, and then calculates acceleration (or a current value) to be applied to the Z-axis movable body 42 through each cylinder mechanism 50, based on the determined pneumatic pressure. When determining the pneumatic pressure, the electro-pneumatic compensation unit 786 calculates a delay time of increase in the pneumatic pressure with respect to elapsed time, and as a result, the acceleration to be applied to the Z-axis movable body 42 also illustrates a variation accounting for the delay time.

The second adder 788 determines a control variable of each drive motor 46 based on the state variables (position, velocity, and acceleration) received from the first calculation unit 783, the second calculation unit 784, the third calculation unit 785, and the electro-pneumatic compensation unit 786. In the position control step (S1), the control variable determined by the second adder 788 is applied to the power supply of each motor mechanism 45 via the mechanism plant unit 782.

Referring back to FIG. 4A, in a torque control step (S2), the stage 30 further raises (overdrives) the wafer W that is moved to a contact position with the probes 22. In this arrangement, the stage 30 can apply an appropriate preload to the probes 22 and ensure an electrical contact between the probes 22 and an electrode pad or a solder bump of the DUT. Specifically, by outputting target drive torques A, B, and C, the stage controller 70 (or the motor drive unit 80) respectively calculates power supply amounts to be supplied to the drive motors 46A, 46B, and 46C (see FIG. 6).

Here, the probes 22 apply a load to the wafer W while elastically deforming due to the preload during an overdrive operation. In this case, when the probes 22 of the probe card 21 and the Z-axis movement mechanism 40 of the stage 30 are regarded as an integral system, the integral system can approximate a response of a second-order system that includes a spring constant and coefficient of kinetic friction.

Specifically, an equation of motion of the inertial system modeled with a spring and friction in a system that includes the probes 22 and the Z-axis movement mechanism 40 is given by Equation (1) below:

$$[ Math . 1 ]$$

$$m \frac{{d}^{2} x}{{dt}^{2}} = - kx - D \frac{dx}{dt} + mg \qquad ( 1 )$$

Here, k is the spring constant, D is the coefficient of kinetic friction, and mg is gravity.

Further, when Laplace transformation is performed on Equation (1) above, the Laplace transformation can be expressed by Equation (2) below:

$$[ Math . 2 ]$$

$${ms}^{2} x = - kx - Dsx + mg \qquad ( 2 )$$

$$( m {s}^{2} + Ds + k ) x = mg$$

$$x = \frac{mg}{m {s}^{2} + Ds + k}$$

Here, s is a complex number obtained by the Laplace transformation of the equation of motion.

In this arrangement, by identifying parameters of the equation of motion in Equation (2), the spring constant k of the system with the probes 22 and the Z-axis movement mechanism 40 can be determined. By determining the spring constant k, the torque that is applied by the probes 22 to the wafer W in the torque control step (S2) can be calculated from F=−kx. However, as described above, the load (spring constant k) that is applied by the system with the probes 22 and the Z-axis movement mechanism 40 may vary due to causes such as inclination of the probe card 21, variation among the probes 22, and wear of the probes during use. In view of the above situation, the test apparatus 1 performs system identification and sets the parameters during maintenance, replacement of the probe card 21, or the like.

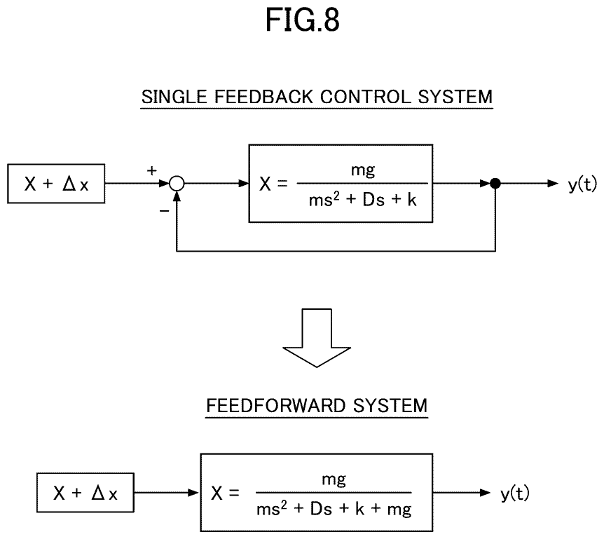

FIG. 8 is an equivalent circuit diagram illustrating the concept of the system identification for the probes 22 and the Z-axis movement mechanism 40. In the system identification, as illustrated in the upper part of FIG. 8, a single feedback system is considered, and a disturbance is applied while the probes 22 are in contact with the wafer W, and parameters (k, D, m) of the system can be identified from a response to the disturbance. The type of disturbance that is applied to the system is not particularly limited, and includes, for example, a random signal, M-sequence, step, Gaussian white noise, or the like.

In the single feedback system illustrated in the upper part of FIG. 8, an actual position is fed back to an input value obtained by adding a disturbance Ax to a target position X. A deviation between the input value and the actual position is input to a calculation unit for identification. By use of Equation (2) above, the calculation unit calculates, as y(t), a temporal change in the system in response to receiving the disturbance. In other words, y (t) a is function of a dynamic characteristic of the system with the probes 22 and the Z-axis movement mechanism 40, in a case of adding the disturbance. The single feedback system can be expressed by the transfer function illustrated in Equation (3) below, and can be regarded as a feedforward system illustrated in the lower part of FIG. 8.

$$[ Math . 3 ]$$

$$x = \frac{mg}{m {s}^{2} + Ds + k + mg} \qquad ( 3 )$$

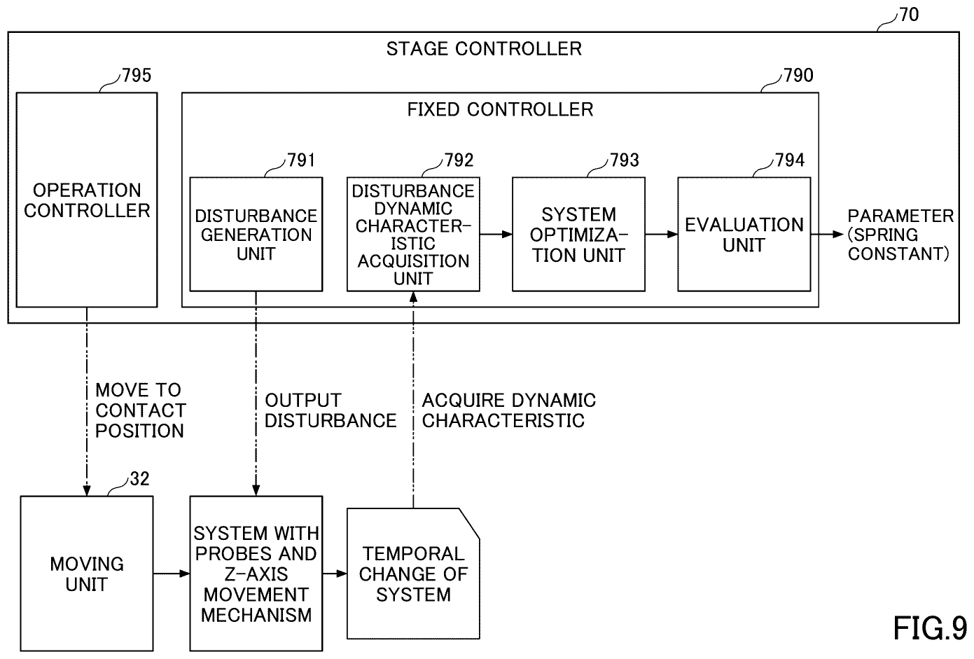

FIG. 9 is a block diagram illustrating a functional block of the stage controller 70 in system identification. The stage controller 70 has an identification controller 790 that performs the system identification. The identification controller 790 includes, for example, a disturbance generation unit 791, a disturbance dynamic characteristic acquisition unit 792, a system optimization unit 793, and an evaluation unit 794. The stage controller 70 also includes an operation controller 795 that controls the movement of the stage 30 in the system identification.

Specifically, in the system identification, the operation controller 795 controls the moving unit 32 to horizontally move the base 35 to a position facing the respective probes 22. Further, at the position facing the probes 22, the operation controller 795 operates the Z-axis movement mechanism 40 to raise the base 35, thereby bringing a wafer W (including a dummy wafer for setting), which is mounted on the base 35, into contact with the probes 22. In other words, the operation controller 795 transfers the wafer W to the contact position with the probes 22.

Then, when the wafer W is placed at the contact position, the disturbance generation unit 791 of the identification controller 790 controls the motor drive unit 80 during an overdrive operation in the system identification to generate a disturbance such as the random signal or the M-series described above, and then the disturbance generation unit 791 outputs the disturbance to each drive motor 46. Each drive motor 46 is driven in response to receiving the disturbance, thereby vibrating the base 35 in a vertical direction (Z-axis direction). At this time, the system with the probes 22 and the Z-axis movement mechanism 40 operates with different vibrations due to error in each component, variations in the drive motors 46, state of each probe 22, and the like.

The disturbance dynamic characteristic acquisition unit 792 of the identification controller 790 acquires a temporal change in the distance at which, in response to receiving the disturbance, the base 35 vibrates as a change in the dynamic characteristic of the system that includes the Z-axis movement mechanism 40. For example, the disturbance dynamic characteristic acquisition unit 792 acquires a plot of the change in the distance, in response to receiving values from the encoders 48 for the drive motors 46 at regular time intervals.

By use of both the acquired change in the distance during vibration and any one of the least squares method, a sequential least squares method, and a Kalman filter, the system optimization unit 793 of the identification controller 790 identifies parameters (k, D, m) of the system including the Z-axis movement mechanism 40. Then, the system optimization unit 793 ultimately acquires the spring constant k from the identified parameters to obtain a drive torque of each drive motor 46 that is required for torque control.

As an example of the system identification, the parameters (k, D, m) of a standard probe card are substituted into Equation (3) above, and the sequential least squares method is used. For example, in the sequential least squares method, a forgetting factor p is introduced into an evaluation function illustrated by Equation (4) below, and an optimum solution of the parameters is obtained by minimizing the evaluation function.

$$[ Math . 4 ]$$

$$EVALUATION FUNCTION \text{:} Jn = {\sum }_{k = 1}^{N} {{ρ}^{N - k} ( {y}_{k} - {z}_{k}^{T} \hat{θ} )}^{2}$$

$$ESTIMATED VALUE \text{:} = ( {\sum }_{K = 1}^{N} {ρ}^{N - k} {z}_{k} {z}_{k}^{T} ) {\sum }_{k = 1}^{N} {ρ}^{N - k} {z}_{k} {y}_{k}$$

$$ALGORITHM \text{:} = + \frac{{P}_{N - 1} {z}_{N}}{ρ + {z}^{T} {}_{N} {P}_{N - 1} {z}_{N}} ( ( {y}_{k} - {z}_{k}^{T} \hat{θ} ) , {P}_{N} = \frac{- 1}{ρ} ( {P}_{N - 1} - \frac{{P}_{N - 1} {z}_{N} {z}^{T} {}_{N} {P}_{N - 1}}{ρ + {z}^{T} {}_{N} {P}_{N - 1} {z}_{N}} )$$

Here, 0<ρ<1:0.95 to 0.999, and P_{N} is a covariance matrix.

The system optimization unit 793 can determine a next setting value yₙ₊₁ from a previous setting value by using the sequential least squares method. For example, when the next setting value yₙ₊₁ is expressed by Equation (5) below, yₙ₊₁ can be expressed by Equation (6).

$$[ Math . 5 ]$$

$${y}_{n + 1} = \frac{1}{1 + {a}_{1} {z}^{- 1} {y}_{1} … + {a}_{n} {z}^{- n} {y}_{n}} \qquad ( 5 )$$

$$[ Math . 6 ]$$

$${θ}^{r =} ( {a}_{1} , {a}_{2} , … , {a}_{n} \} , {z}^{T} = ( - {y}_{t - 1} , - {y}_{t - 2} , … , - {y}_{t - n} ) \qquad ( 6 )$$

When the parameters (k, D, m) in Equation (3) are identified in the system identification, the evaluation unit 794 of the identification controller 790 determines whether the identified parameters are included within a preset allowable range. If the parameters are included within the allowable range, the evaluation unit 794 terminates the system identification, and extracts the spring constant k from the parameters. As described above, the spring constant k is used to determine a torque applied by the probes 22 of the system with the probes 22 and the Z-axis movement mechanism 40. In this arrangement, in the torque control step p (S2), the stage controller 70 can simply set a driving torque of each drive motor 46, based on the spring constant k.

On the other hand, if the identified parameters are out of the allowable range, the evaluation unit 794 determines whether to retry the system identification. In this retry of the system identification, the stage controller 70 applies the next setting value yₙ₊₁ that is obtained by Equations (5) and (6) that change the above weighting. Then, the stage controller 70 generates noise again, and performs the above system identification again by acquiring the dynamic characteristic at the current time.

By obtaining the spring constant k through the above system identification, the stage controller 70 can accurately obtain a target driving torque in the torque control step (S2), and the target driving torque corresponds to the current state of the system (error in each component, machine deviation of the drive motor 46, and state of each probe 22).

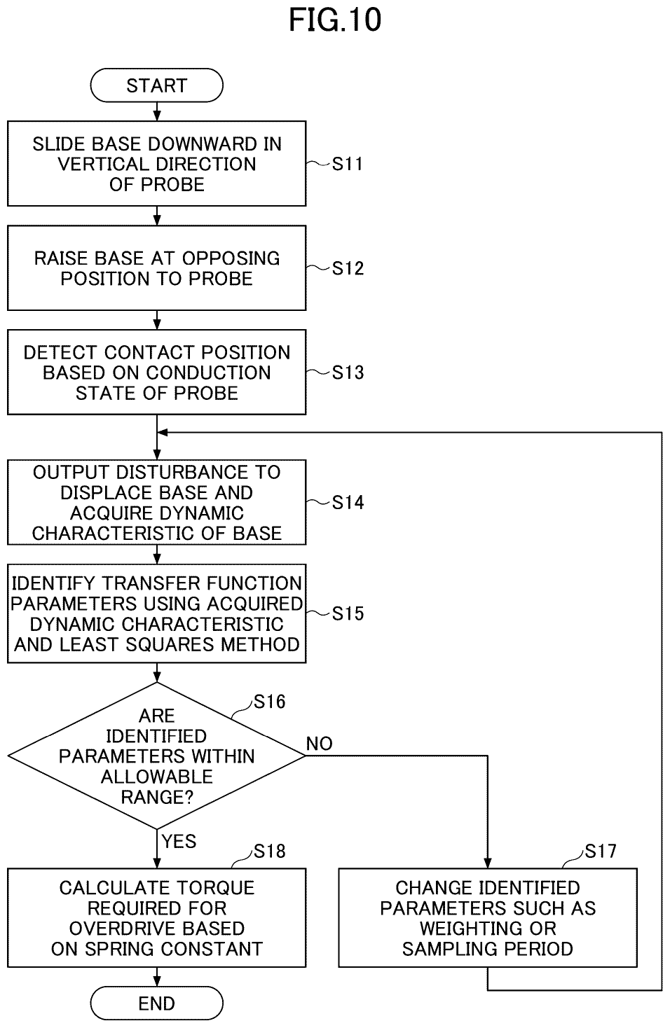

The test apparatus 1 and the stage 30 according to the present embodiment are basically configured as described above, and the operation (a method for setting parameters) executed by the test apparatus 1 and the stage 30 will be described below with reference to FIG. 10. FIG. 10 is a flowchart illustrating a process flow of the method for setting parameters.

During maintenance, replacement of the probe card 21, or the like, the stage controller 70 of the test apparatus 1 starts system identification based on a command from the controller 90 (operator). Before starting the system identification, the wafer W (or the dummy wafer) is placed on the mounting surface 30s of the base 35.

As a preliminary operation for the system identification, the stage controller 70 first controls the moving unit 32 of the stage 30 through the operation controller 795 to slide the stage 30 downward in a vertical direction of the probes 22 (step S11). Further, the operation controller 795 raises the base 35 with the wafer W at a position facing the probes 22 (step S12).

Then, the stage controller 70 monitors a conduction state of the probes 22 and detects a contact position of the dummy wafer with the probes 22 (step S13). Based on the detection of the contact position, the stage controller 70 starts system identification.

Specifically, by outputting noise through the disturbance generation unit 791, the stage controller 70 and acquires displaces the base 35, a dynamic characteristic of the base 35 at the current time through the disturbance dynamic characteristic acquisition unit 792 (step S14).

Then, the system optimization unit 793 identifies parameters (k, D, m) of the system in Equation (3) above, by using the acquired dynamic characteristic and the sequential least squares method (step S15).

Then, the evaluation unit 794 determines whether the identified parameters are within an allowable range (step S16). If the identified parameters are outside the allowable range (No in step S16), the process proceeds to step S17. On the other hand, if the identified parameters are within the allowable range (Yes in step S16), the process proceeds to step S18.

In step S17, the system optimization unit 793 changes the identified parameters in the system identification, such as weighting or sampling period. Then, the stage controller 70 returns to step S14 and repeats steps S14 to S16.

On the other hand, in step S18, the stage controller 70 calculates torque required for overdrive in the torque control step (S2), based on the spring constant k of the identified parameters.

When the above parameter setting method is completed, the stage controller 70 enables the test apparatus 1 to actually test the wafer W. In the test of the wafer W, the stage controller 70 performs the position control step (S1) and the torque control step (S2) in FIG. 4A. In the torque control step (S2), the stage controller 70 outputs, as a target driving torque, torque based on the spring constant k, to the third deviation units 76A to 76C on the input side of the third calculation units 73A to 73C illustrated in FIG. 6. Thus, the test apparatus 1 can appropriately control the height of the base 35 in the torque control step (S2).

The test apparatus 1 and the parameter setting method of the present disclosure are not limited to the above embodiments, and various modifications may be made. For example, although the Z-axis movement mechanism 40 includes three drive units 41 to support the base 35 on the surface in the embodiments, the Z-axis movement mechanism 40 may include four or more drive units 41. Further, for example, although the stage 30 of the test apparatus 1 includes two types of mechanisms, namely the motor mechanism 45 and the cylinder mechanism 50 in the embodiment, only one type of mechanism may be adopted. For example, even in a case of the motor mechanism 45 alone, the stage 30 can satisfactorily obtain parameters during the upward movement of the base 35 by performing the above system identification.

Further, in the above embodiment, the position (rotational position) of each drive motor 46 is obtained as a dynamic characteristic when outputting the disturbance to the Z-axis movement mechanism 40. However, the test apparatus 1 may obtain the dynamic characteristic by various methods. As an example, the test apparatus 1 includes a sensor that detects a height position of the base 35 and then may obtain the dynamic characteristics through the sensor. Alternatively, the test apparatus 1 detects the current that is supplied to the drive motors 46 by the current sensor 49 under disturbance, and then may obtain the dynamic characteristic using a detection result by the current sensor 49. Alternatively, in this case, the detection result may be used for correction of a dynamic characteristic that is obtained separately. Further, the test apparatus 1 includes a pressure sensor 59 (see dotted line in FIG. 3) that detects pressure generated in each recess 52, and in this case, the test apparatus 1 may obtain the dynamic characteristic using a detection result obtained by the pressure sensor 59 under disturbance. Alternatively, in this case, the detection result may be used for correction of a dynamic characteristic that is obtained separately.

A technical concept and effects of the present disclosure provided in the above embodiment(s) will be described below.

A first aspect of the present disclosure is a test apparatus 1 that includes a base 35 on which a substrate (wafer W) is to be mounted; an elevating mechanism (Z-axis movement mechanism 40) configured to raise and lower the base 35; a test unit 10 configured to test the substrate while contacting the substrate; and a controller (a controller 90 and a stage controller 70) configured to control the elevating mechanism. The controller is configured to generate a disturbance in the elevating mechanism at a position where the test unit 10 contacts the substrate, acquire a dynamic characteristic of the elevating mechanism due to the disturbance, and set one or more parameters during upward movement of the elevating mechanism, based on the dynamic characteristic of the elevating mechanism.

In the above aspect, the test apparatus 1 can accurately set one or more parameters when raising the base 35. That is, by setting the one or more parameters based on the dynamic characteristic of the elevating mechanism (Z-axis movement mechanism 40) due to the disturbance, the test apparatus 1 can obtain the one or more parameters that correspond to the present elevating mechanism and a state of the test unit 10. In this arrangement, by utilizing the one or more parameters, the test apparatus 1 can accurately estimate torque that is applied from the test unit 10 to the base 35, and thus can appropriately control the elevating mechanism by using the torque.

A test unit 10 may have probes 22 in contact with a substrate (wafer W), and one or more parameters may include a spring constant k for the probes 22 during an overdrive operation in which the substrate is further raised from a contact position. By use of the spring constant k, it is possible to sufficiently approximate torque applied by the probes 22 to the wafer W and a base 35 during an actual overdrive operation.

A controller (a controller 90 and a stage controller 70) may calculate torque that is applied by probes 22 to an elevating mechanism (Z-axis movement mechanism 40) during an overdrive operation, based on a calculated spring constant k. In this arrangement, a test apparatus 1 can easily and accurately obtain a target drive torque during the overdrive operation.

One or more parameters may be the parameters of an equation of motion of the following equation (A) in which, when probes 22 and an elevating mechanism (Z-axis movement mechanism 40) are used as one system, a spring constant is k, the coefficient of dynamic friction is D, and the mass is m. In this arrangement, a test apparatus 1 can obtain the spring constant k with high accuracy.

$$x = mg / ( {ms}^{2} + Ds + k + mg ) \qquad ( A )$$

Here, s is a complex number obtained by Laplace transformation of the equation of motion.

A controller (a controller 90 and a stage controller 70) may identify one or more parameters by using both a dynamic characteristic of an elevating mechanism (Z-axis movement mechanism 40) and any one of the least squares method, the sequential least squares method, and a Kalman filter. In this arrangement, a test apparatus 1 can satisfactorily calculate one or more parameters when raising the elevating mechanism.

Displacement of a base due to a disturbance may be less than a rise amount of a substrate that is tested during an overdrive operation. In this arrangement, a test apparatus 1 can efficiently set one or more parameters without applying a large load to the probes 22.

A controller (a controller 90 and a stage controller 70) may determine a wear state of probes 22 from calculated parameter(s). In this arrangement, a test apparatus 1 can appropriately determine a replacement timing of a probe card 21.

A controller (a controller 90 and a stage controller 70) may output a disturbance to an elevating mechanism (Z-axis movement mechanism 40) to raise and lower a base 35. In this arrangement, a test apparatus 1 can obtain a dynamic characteristic when raising and lowering the base 35, and can stably identify parameter(s).

A disturbance may include any one of a random signal, M-sequence, step, and normal distribution white noise. In this case, a test apparatus 1 can generate the disturbance to an elevating mechanism (Z-axis movement mechanism 40).

An elevating mechanism (Z-axis movement mechanism 40) may have a first adjusting mechanism (motor mechanism 45) configured to adjust an elevation position of a base 35 by rotational driving of a drive motor 46, and may include a second adjusting mechanism (cylinder mechanism 50) configured to adjust the elevating position of the base 35 by supplying and discharging a pressure medium. In this arrangement, a test apparatus 1 can easily and accurately raise and lower the base 35 while reducing costs of the base 35 during raising and lowering.

Three or more first adjusting mechanisms (motor mechanisms 45) and second adjusting mechanisms (cylinder mechanisms 50) may be installed under a base 35 to individually raise and lower the base 35 at the installed positions. With the three or more first adjusting mechanisms and second adjusting mechanisms, a test apparatus 1 can easily and accurately adjust the tilt or the like of the base 35.

A test apparatus 1 may include a position sensor (encoder 48) configured to detect a position of a drive motor 46 or a position of a base 35 as a dynamic characteristic of an elevating mechanism (Z-axis movement mechanism 40) in response to a disturbance. In this arrangement, the test apparatus 1 can satisfactorily obtain the dynamic characteristic when the base 35 is displaced.

A test apparatus 1 may include a current sensor 49 configured to detect a current supplied to a drive motor 46 as a dynamic characteristic of an elevating mechanism (Z-axis movement mechanism 40) in response to a disturbance. In this arrangement, the test apparatus 1 can appropriately utilize a change in the current when the base 35 is displaced due to the disturbance.

A test apparatus 1 may include a pressure sensor 59 configured to detect pressure of a pressure medium in a second adjusting mechanism (cylinder mechanism 50) as a dynamic characteristic of an elevating mechanism (Z-axis movement mechanism 40), in response to a disturbance. In this arrangement, the test apparatus 1 can appropriately utilize a change in the pressure when a base 35 is displaced due to the disturbance.

A drive motor 46 may be a direct drive motor. In this case, a test apparatus 1 can be made as compact as possible, and direct torque control can be easily realized without a reduction gear.

A second aspect of the present disclosure is a method for setting parameters executed by a test apparatus 1 including a base 35 on which a substrate (wafer W) is to be mounted; an elevating mechanism (Z-axis movement mechanism 40) configured to raise and lower the base 35; a test unit 10 configured to test the substrate while contacting the substrate that is raised and lowered, and a controller (a controller 90 and a stage controller 70) configured to control the elevating mechanism. The method includes generating a disturbance in the elevating mechanism at a position where the test unit 10 contacts the substrate; acquiring a dynamic characteristic of the elevating mechanism due to the disturbance; and setting one or more parameters during upward movement of the elevating mechanism, based on the dynamic characteristic of the elevating mechanism. In this case, in the method, parameter(s) during raising of the base 35 can be set accurately.

The test apparatus 1 and the method for setting parameters of the present disclosure are examples in all aspects, and are not limiting. While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

In the present disclosure, parameter(s) during raising of a base can be set accurately.

1. A test apparatus comprising:
a base on which a substrate is to be mounted;
an elevating mechanism configured to raise and lower the base;
a test unit configured to test the substrate while contacting the substrate that is raised and lowered; and
a controller configured to:
control the elevating mechanism,
generate a disturbance in the elevating mechanism at a position where the test unit contacts the substrate,
acquire a dynamic characteristic of the elevating mechanism due to the disturbance, and
set one or more parameters during upward movement of the elevating mechanism, based on the dynamic characteristic of the elevating mechanism.

2. The test apparatus according to claim 1, wherein the test unit includes probes in contact with the substrate, and
wherein the one or more parameters include a spring constant for the probes during an overdrive operation in which the substrate is further raised from the position.

3. The test apparatus according to claim 2, wherein the controller is configured to calculate, based on the spring constant, torque that is applied to the elevating mechanism by the probes during the overdrive operation.

4. The test apparatus according to claim 2, wherein the probes and the elevating mechanism constitute a single system, and the one or more parameters are parameters of an equation of motion of Equation below:
$$x = mg / ( {ms}^{2} + Ds + k + mg )$$
where, k is the spring constant, D is coefficient of kinetic friction, m is mass, and s is a complex number obtained by Laplace transformation of the equation of motion.

5. The test apparatus according to claim 4, wherein the controller is configured to identify the one or more parameters, using the dynamic characteristic of the elevating mechanism and one of a least squares method, a sequential least squares method, or a Kalman filter.

6. The test apparatus according to claim 2, wherein displacement of the base due to the disturbance is less than a rise amount of the substrate that is tested during the overdrive operation.

7. The test apparatus according to claim 2, wherein the controller is configured to determine a wear state of the probes from the calculated one or more parameters.

8. The test apparatus according to claim 1, wherein the controller is configured to output the disturbance to the elevating mechanism to raise and lower the base based on the disturbance.

9. The test apparatus according to claim 1, wherein the disturbance includes any one of a random signal, M-sequence, step, and normal distribution white noise.

10. The test apparatus according to claim 1, wherein the elevating mechanism includes:
a first adjusting mechanism configured to adjust an elevation position of the base by rotational driving of a drive motor, and
a second adjusting mechanism configured to adjust the elevation position of the base by supplying and discharging a pressure medium.

11. The test apparatus according to claim 10, wherein three or more first adjusting mechanisms and second adjusting mechanisms are provided under the base, to individually raise and lower the base at respective positions.

12. The test apparatus according to claim 10, further comprising:
a position sensor configured to detect a position of the drive motor or a position of the base as the dynamic characteristic of the elevating mechanism, in response to the disturbance.

13. The test apparatus according to claim 10, further comprising:
a current sensor configured to detect a current supplied to the drive motor as the dynamic characteristic of the elevating mechanism, in response to the disturbance.

14. The test apparatus according to claim 10, further comprising:
a pressure sensor configured to detect pressure of the pressure medium in the second adjusting mechanism as the dynamic characteristic of the elevating mechanism in response to the disturbance.

15. The test apparatus according to claim 10, wherein the drive motor is a direct drive motor.

16. A method for setting parameters executed by a test apparatus including:
a base on which a substrate is to be placed,
an elevating mechanism configured to raise and lower the base,
a test unit configured to test the substrate while contacting the substrate that is raised and lowered, and a controller configured to control the elevating mechanism, the method comprising:
generating a disturbance in the elevating mechanism, at a position where the test unit contacts the substrate;
acquiring a dynamic characteristic of the elevating mechanism due to the disturbance; and
setting one or more parameters during upward movement of the elevating mechanism, based on the dynamic characteristic of the elevating mechanism.
